(19) United States
(12) Patent Application Publication
(10) Pub. No.: US 2023/0069162 A1
(43) Pub. Date: Mar. 2, 2023

(54) SERVER AND CHASSIS THEREOF

(71) Applicants: SQ TECHNOLOGY (SHANGHAI) CORPORATION, Shanghai (CN); INVENTEC CORPORATION, Taipei City (TW)

(72) Inventors: Shuai ZHANG, Shanghai (CN); Haiting CHEN, Shanghai (CN); Guangzhao TIAN, Shanghai (CN)

(21) Appl. No.: 17/520,299

(22) Filed: Nov. 5, 2021

(30) Foreign Application Priority Data
Aug. 31, 2021 (CN) 202111013385.1

(51) Int. Cl. H05K 7/20; H05K 7/14

(52) U.S. Cl. CPC H05K 7/20727; H05K 7/1487; H05K 7/1492

(57) ABSTRACT

A server and a chassis of the server are disclosed. The server chassis includes a casing and a fan tray. The casing has a front side and an opposing rear side. The fan tray is disposed on the front or rear side of the casing in a flippable manner. This design allows the chassis to be applicable to different types of servers, resulting in reduced research, development and manufacturing cost of the server and chassis.

### CROSS-REFERENCES TO RELATED APPLICATION

This application claims the priority of Chinese patent application number 202111013385.1, filed on Aug. 31, 2021, the entire contents of which are incorporated herein by reference.

### TECHNICAL FIELD

The present invention relates to a server and a chassis thereof, and particularly to a multi-purpose server and a chassis thereof.

### BACKGROUND

In this contemporary era featuring the rapid development of information technology (IT), both businesses and individuals have for long used personal computers (PCs) (e.g., desktops, laptops, etc.) to handle their daily affairs. Moreover, with the increasing maturation of the communications industry, transnational e-commerce has displayed a trend to replace the traditional regional business culture, making general-purpose PCs increasingly incapable of satisfying businesses' commercial needs. Catering for these needs, computer manufacturers have developed various forms of servers (e.g., cabinet servers, blade servers, tower servers or the like).

A server typically includes a chassis and internal electronic components. In view of efficient heat dissipation and spatial utilization, research and development (R&D) designers usually design dedicated chassis using building blocks of internal electronic components. However, with new server models being frequently introduced, there will be some incorporating changes in building blocks of internal electronic components, which may make some existing chassis specially designed for such building blocks not suitably usable anymore. That is to say, once a new server model is introduced, it may be necessary for the manufacturer to design a new chassis for dedicated use for it. As a result, developing more models will lead to increased average R&D and manufacturing cost per unit.

### SUMMARY OF THE INVENTION

The present invention seeks to provide a server and a chassis thereof, which is commonly usable by different server models and thus can results in lower server and server chassis R&D and manufacturing cost.

In one embodiment of the present invention, there is disclosed a server chassis including a casing and a fan tray. The casing has a front side and an opposing rear side. The fan tray is disposed on the front or rear side in a flippable manner.

In another embodiment of the present invention, there is disclosed a server including a chassis and a fan module. The chassis includes a casing and a fan tray. The casing has a front side and an opposing rear side. The fan tray is disposed on the front or rear side in a flippable manner. The fan module is provided in the fan tray.

In the server and chassis according to the above embodiments, since the mounting trays for the functional modules, such as the fan tray, the power tray and the switch tray, are all designed to be independently attachable and detachable, the server may be configured in either a standard configuration or a rack mount configuration as needed. This helps to reduce R&D and manufacturing cost of the server and chassis thereof.

Further, the configuration of the server is more flexible because a user may adapt handle positions to the configuration of the server.

Furthermore, different structures of first and second assembly features of the fan tray allow an operator to mount a fan in a correct orientation.

Both the above summary and the following detailed description are exemplary and illustrative of the principles of the present invention and are intended to provide a further explanation of the scope of the invention.

### BRIEF DESCRIPTION OF THE DRAWINGS

FIG. 1 shows a stereoscopic schematic representation of a server according to a first embodiment of the present invention.

FIG. 2 is an exploded schematic diagram of FIG. 1.

FIG. 3 shows a stereoscopic schematic representation of a server according to a second embodiment of the present invention.

FIG. 4 is an exploded schematic diagram of FIG. 2.

FIG. 5 is an exploded schematic diagram of the fan tray of FIGS. 1 or 2 and a fan.

1, 1A ... Server
10 ... Chassis
20 ... Fan Module
22 ... Through Hole
24 ... Locating Pin
26 ... Attachment Bolt
30 ... Switch Module
40 ... Power Module
50 ... Power Module
100 ... Casing
101 ... Front Side
102 ... Rear Side
110 ... Coupling Hole
200 ... Fan Tray
201 ... Upwind Side
202 ... Downwind Side
210 ... First Assembly Feature
220 ... Second Assembly Feature
250 ... Fan Back Plate
300 ... Switch Tray
400 ... Power Tray
500 ... Front Tray
600 ... Handle
650 ... Coupling Member
700 ... Air Director
800 ... Cover Plate

### DETAILED DESCRIPTION

A server 1 according to an embodiment may employ, for example, a multi-graphics processing unit (GPU) system, which is required to have not only high bandwidth performance between the GPUs and a central processing unit (CPU) but also very high bandwidth performance between the GPUs themselves (i.e., peer-to-peer). As an example, the multi-GPU system may include a CPU, multiple GPUs, a switch supporting a bus communication protocol, and/or a manager. The multiple GPUs may be communicatively connected to the CPU. The switch may be connected to the multiple GPUs to enable inter-GPU communications. The manager may be communicatively connected to, and thus be able to manage, the switch.

The server 1 according to this embodiment solves the problem of relatively low peer-to-peer communication bandwidths between the GPUs and enables high bandwidths between the GPUs and the CPU. When implemented as a secondary PCIe card, the switch allows direct data exchange between the GPU systems in the network without involving the CPU or memory thereof, resulting in greatly enhanced data exchange performance between the GPU systems. Additionally, the present invention can maximize and equalize peer-to-peer communication bandwidths between the GPUs, theoretically as high as 300 GB/s. Further, another 8-GPU system can be included to resulting in an extension to a 16-GPU system capable of peer-to-peer communication between any two GPUs.

The height of the server 1 may be, for example, but is not limited to, 4U. It includes a chassis 10 and a fan module 20. The chassis 10 includes a casing 100 and a fan tray 200. The casing 100 has a front side 101 and an opposing rear side 102. The casing 100 may have coupling holes 110 arranged on the front 101 and rear 102 side of the casing 100. The fan tray 200 may have an upwind side 201 and an opposing downwind side 202 and is disposed on the front 101 or rear side 102 of the casing 100 in a flippable manner so that the server 1 assumes a standard configuration or a rack mount configuration. Further, the fan tray 200 may be so disposed that its upwind side 201 is closer to the front side 101 of the casing 100 than the downwind side 202 of the fan tray 200.

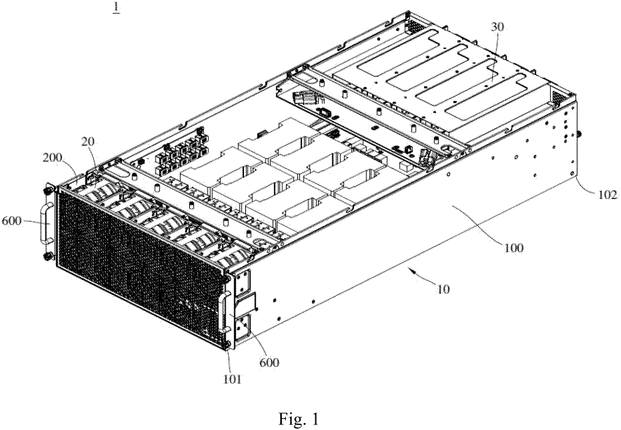

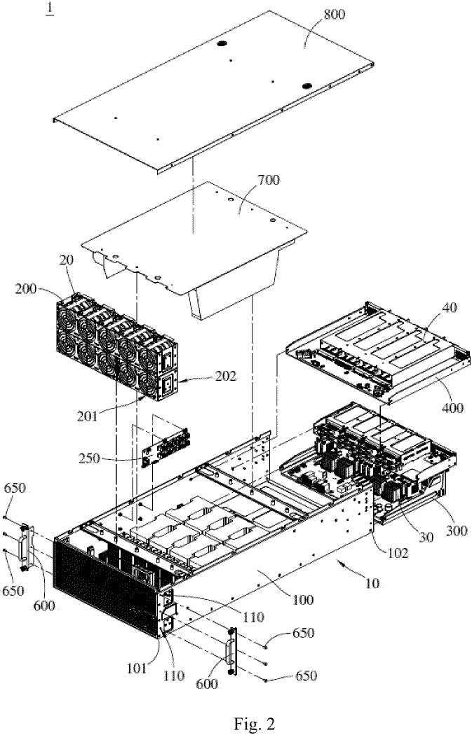

FIGS. 1 and 2 show an example of the server 1 in a standard configuration. FIG. 1 shows a stereoscopic schematic representation of the server 1 according to a first embodiment of the present invention. FIG. 2 is an exploded schematic diagram of FIG. 1.

The server 1 according to this embodiment assumes, for example, a standard configuration and includes a chassis 10 and a fan module 20. The chassis 10 includes a casing 100 and a fan tray 200. The casing 100 has a front side 101 and an opposing rear side 102. The casing 100 additionally has coupling holes 110 arranged on the front 101 and rear 102 side of the casing 100. The fan tray 200 is disposed on the front side 101 of the casing 100, and has an upwind side 201 and an opposing downwind side 202. The fan tray 200 is disposed so that its upwind side 201 is closer to the front side 101 of the casing 100 than the downwind side 202 of the fan tray 200. The fan module 20 is provided in the fan tray 200. The server 1 may further include a fan back plate 250 mounted on the chassis 10 and multiple electrical connectors for enabling electrical connection of the fan module 20.

In this and other embodiments, the chassis 10 of the standardly configured server 1 may further include a switch module 30 and a power module 40. The chassis 10 may further include a switch tray 300 and a power tray 400, which are both disposed on the front side 101 of the casing 100 in an insertably removable and replaceable manner. The power tray 400 may be positioned above the switch tray 300. The switch module 30 is provided in the switch tray 300. The power module 40 is provided in the power tray 400 and configured to provide electrical power to the server 1.

In this and other embodiments, the chassis 10 of the standardly configured server 1 may further include handles 600 and coupling members 650. The handles 600 may be attached to the front side 101 of the casing 100 via the coupling members 650 and the coupling holes 110.

In this and other embodiments, the chassis 10 of the standardly configured server 1 may further include an air director 700 and a cover plate 800. The air director 700 may be disposed on the casing 100 and configured to guide an air flow produced by the fan module 20. The cover plate 800 may be mounted on the casing 100 so as to cover the latter.

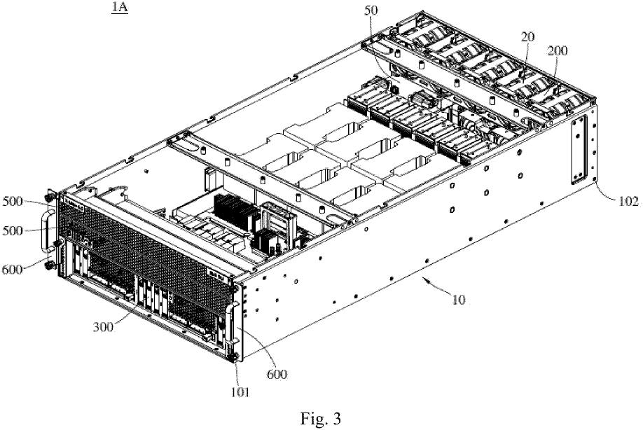

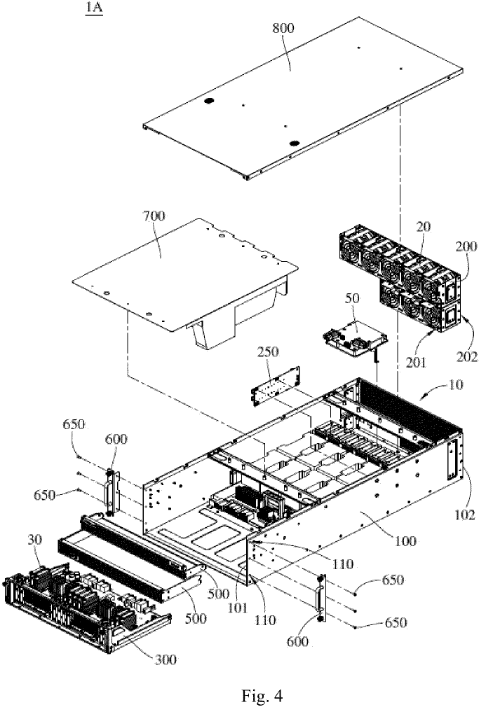

FIGS. 3 and 4 show an example of the server 1A in a rack mount configuration. FIG. 3 shows a stereoscopic schematic representation of the server 1A according to a second embodiment of the present invention. FIG. 4 is an exploded schematic diagram of FIG. 2.

The server 1A according to this embodiment assumes, for example, a rack mount configuration and includes a chassis 10 and a fan module 20. The chassis 10 includes a casing 100 and a fan tray 200. The casing 100 has a front side 101 and a rear side 102. The casing 100 additionally has coupling holes 110 arranged on the front 101 and rear 102 side of the casing 100. The fan tray 200 is disposed on the rear side 102 of the casing 100, and has an upwind side 201 and an opposing downwind side 202. The fan tray 200 is disposed so that its upwind side 201 is closer to the front side 101 of the casing 100 than the downwind side 202 of the fan tray 200. The fan module 20 is provided in the fan tray 200. The server 1A may further include a fan back plate 250 mounted on the chassis 10 and multiple electrical connectors for enabling electrical connection of the fan module 20.

In this and other embodiments, the chassis 10 of the rack mount server 1A may further include a switch module 30 and a power module 50. The chassis 10 may further include a switch tray 300 and multiple front trays 500, which are both disposed on the front side 101 of the casing 100 in an insertably removable and replaceable manner. The front trays 500 may be positioned above the switch tray 300. The switch module 30 is provided in the switch tray 300. The power module 50 is disposed under the fan tray 200, and is connected to a rack power strip to provide electrical power to the server 1A.

In this and other embodiments, the chassis 10 of the rack mount server 1A may further include handles 600 and coupling members 650. The handles 600 may be attached to the front side 101 of the casing 100 via the coupling members 650 and the coupling holes 110.

In this and other embodiments, the chassis 10 of the rack mount server 1A may further include an air director 700 and a cover plate 800. The air director 700 may be disposed on the casing 100 and configured to guide an air flow produced by the fan module 20. The cover plate 800 may be mounted on the casing 100 so as to cover the latter.

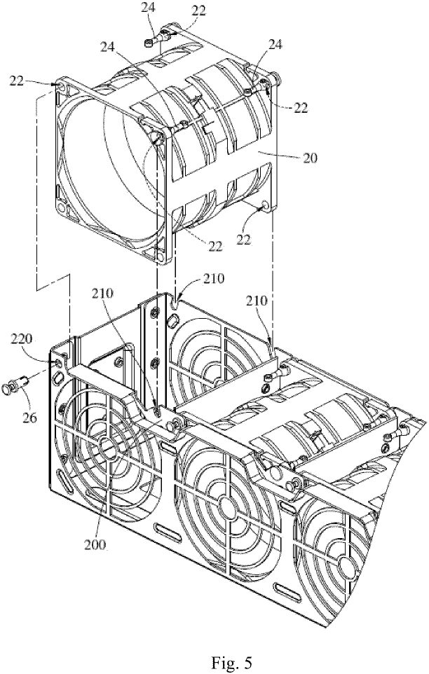

Reference is now made to FIG. 5, an exploded schematic diagram of the fan tray 200 of FIGS. 1 or 2 and a fan.

The fan tray 200 may have at least one first assembly feature 210 and at least one second assembly feature 220, which are configured for assembly of a fan and structured differently. For example, the at least one first assembly feature 210 may be semicircular hole(s), while the at least one second assembly feature 220 may be round hole(s). The fan module 20 may have multiple through holes 22, and locating pins 24 like plastic nails may be inserted in some of the through holes 22. The positions and number of the locating pins 24 may match the positions and number of the first assembly feature(s) 210. In order to mount the fan module 20 into the fan tray, as the first assembly feature(s) 210 is/are semicircular hole(s), an operator may directly seat the fan module 20 into the fan tray so that one or more of the locating pins 24 are snapped in the first assembly feature(s) 210.

Once the fan module 20 is seated in the fan tray, bolt(s) 26 may be inserted through the respectively second assembly feature(s) 220 and respective other through hole(s) 22 to fix the fan module 20 to the fan tray.

In the server and chassis according to the above embodiments, since the mounting trays for the functional modules, such as the fan tray, the power tray and the switch tray, are all designed to be independently attachable and detachable, the server may be configured in either a standard configuration or a rack mount configuration as needed. This helps to reduce R&D and manufacturing cost of the server and chassis thereof.

Further, the configuration of the server is more flexible because a user may adapt the positions of the handles to the configuration of the server.

Furthermore, the different structures of the first and second assembly features of the fan tray allow an operator to mount a fan in a correct orientation.

Although the present invention has been disclosed above with reference to the foregoing embodiments, it is in no way limited to thereto. Any person of ordinary skill in the art can make some changes and modifications without departing from the spirit and scope of the invention. Accordingly, the scope of the present invention is intended to be defined by the appended claims.

1. A server chassis, comprising:
a casing having a front side and a rear side opposing the front side; and
a fan tray disposed on the front side or the rear side in a flippable manner, so that the fan tray is able to change its position between the front side and the rear side of the casing,
wherein the fan tray comprises at least one first assembly feature and at least one second assembly feature, which are configured for assembly of a fan module and are structured differently.

2. The server chassis of claim 1, further comprising a power tray disposed on the casing in an insertably removable and replaceable manner and configured for the mounting of a power module therein.

3. The server chassis of claim 1, further comprising a front tray disposed on the casing in an insertably removable and replaceable manner.

4. The server chassis of claim 3, further comprising a switch tray detachably disposed on the casing, wherein the front tray is disposed above the switch tray, and the switch tray is configured for mounting of a switch module therein.

5. The server chassis of claim 1, further comprising a handle and at least one coupling member, wherein at least one coupling hole is provided on both the front side and the rear side of the casing, and wherein the handle is attached to the front side of the casing via the at least one coupling member and the at least one coupling hole on the front side, or to the rear side of the casing via the at least one coupling member and the at least one coupling hole on the rear side.

6. (canceled)

7. The server chassis of claim 1, wherein the at least one first assembly feature is/are semicircular hole(s), and the at least one second assembly feature is/are round hole(s).

8. A server, comprising:
a chassis, comprising:
a casing having a front side and a rear side opposing the front side; and
a fan tray disposed on the front side or the rear side in a flippable manner, so that the fan tray is able to change its position between the front side and the rear side of the casing; and
a fan module provided in the fan tray.

9. The server of claim 8, further comprising a switch module and a power module, wherein the chassis further comprises a switch tray and a power tray, which are both disposed on the front side of the casing in an insertably removable and replaceable manner, the power tray disposed above the switch tray, the switch module provided in the switch tray, the power module provided in the power tray.

10. The server of claim 8, further comprising a switch module and a power module, wherein the chassis further comprises a switch tray and a front tray, which are both disposed on the front side of the casing in an insertably removable and replaceable manner, the front tray disposed above the switch tray, the switch module provided in the switch tray, the power module provided under the fan tray.
